(19) United States
(12) Patent Application Publication
(10) Pub. No.: US 2026/0259499 A1
(43) Pub. Date: Sep. 3, 2026

(54) PHOTOSENSITIVE RESIN COMPOSITION, PHOTOSENSITIVE ELEMENT, PRINTED WIRING BOARD, AND METHOD FOR MANUFACTURING PRINTED WIRING BOARD

(71) Applicant: Resonac Corporation, Minato-ku, Tokyo (JP)

(72) Inventors: Yuta DAIJIMA, Minato-ku, Tokyo (JP); Shuji NOMOTO, Minato-ku, Tokyo (JP); Akihiro NAKAMURA, Minato-ku, Tokyo (JP); Naomitsu KOMORI, Minato-ku, Tokyo (JP); Mana HIRAHARA, Minato-ku, Tokyo (JP)

(21) Appl. No.: 18/858,074

(22) PCT Filed: Dec. 20, 2023
(86) PCT No.: PCT/JP2023/045772

§ 371 Date: Oct. 18, 2024

(30) Foreign Application Priority Data
Dec. 21, 2022 (JP) 2022-204341

(51) Int. Cl. G03F 7/075; G03F 7/40; H05K 1/03; H05K 3/02

(52) U.S. Cl. CPC G03F 7/0755; G03F 7/40; H05K 1/0373; H05K 3/027; H05K 2201/0209

(57) ABSTRACT

The photosensitive resin composition for permanent resist according to the present disclosure contains (A) an acid-modified vinyl group-containing resin, (B) a photopolymerizable compound, (C) a photopolymerization initiator, (D) an inorganic filler, and (E) an organosilane compound, and the inorganic filler includes a surface-treated filler.

### TECHNICAL FIELD

The present disclosure relates to a photosensitive resin composition for permanent resist, a photosensitive element, a printed wiring board, and a method for producing a printed wiring board.

### BACKGROUND ART

In the field of printed wiring boards, a permanent resist is formed on a printed wiring board. A permanent resist has a role of preventing corrosion of the conductor layers or maintaining electric insulation between the conductor layers when the printed wiring board is in use. In recent years, a permanent resist also has a role as a solder resist film that prevents solder from adhering to an unnecessary portion of the conductor layer of a printed wiring board in a process in which a semiconductor element is mounted on a printed wiring board via solder by flip chip mounting, wire bonding or the like as well.

Hitherto, permanent resists have been prepared by a screen printing method using a thermosetting resin composition or a photographic method using a photosensitive resin composition. For example, in flexible wiring boards using mounting methods such as FC (flip chip), TAB (tape automated bonding), and COF (chip on film), a thermosetting resin paste is screen printed except for the parts such as IC chips, electronic components, or LCD (liquid crystal display) panels and connecting wiring patterns, and then thermally cured to form a permanent resist (for example, see Patent Literature 1).

In semiconductor package substrates, such as BGA (ball grid array) and CSP (chip size package), that are mounted on electronic components, it is necessary to remove the permanent resist from the joining portions (1) in order to flip-chip mount a semiconductor element on a semiconductor package substrate via solder, (2) in order to join a semiconductor element to a semiconductor package substrate by wire bonding, or (3) in order to join a semiconductor package substrate to a motherboard substrate by soldering. For image formation of permanent resist, a photographic method is used in which a photosensitive resin composition is applied, dried, and then cured by being selectively irradiated with actinic light such as ultraviolet light, and only the unirradiated portions are removed by development to form an image. A photographic method is suitable for mass production because of its favorable working properties and is thus widely used in the electronic materials industry for image formation of photosensitive materials (for example, see Patent Literature 2).

### CITATION LIST

### Patent Literature

Patent Literature 1: JP 2003-198105 A
Patent Literature 2: JP H11-240930 A

### SUMMARY OF INVENTION

### Technical Problem

In response to the increase in density of printed wiring boards, permanent resists are also required to exhibit higher performance, and in particular, required to exhibit all of fine pattern formability (resolution), thermal shock resistance, heat resistance, and insulation properties at high degrees.

An object of the present disclosure is to provide a photosensitive resin composition capable of forming a permanent resist that is excellent in resolution, thermal shock resistance, heat resistance, and insulation properties, a photosensitive element and a printed wiring board each obtained using the photosensitive resin composition, and a method for producing a printed wiring board.

### Solution to Problem

An aspect of the present disclosure relates to the following photosensitive resin composition, photosensitive element, printed wiring board, and method for producing a printed wiring board.
[1] A photosensitive resin composition for permanent resist containing:
(A) an acid-modified vinyl group-containing resin; (B) a photopolymerizable compound; (C) a photopolymerization initiator; (D) an inorganic filler; and (E) an organosilane compound, in which (D) the inorganic filler includes a surface-treated filler.
[2] The photosensitive resin composition according to [1], in which the surface-treated filler is an inorganic filler that has undergone surface treatment with at least one surface treatment agent selected from the group consisting of an organozirconium compound, an organotitanium compound, an organoaluminium compound, and an organosilane compound.
[3] The photosensitive resin composition according to [1] or [2], in which (E) the organosilane compound includes at least one selected from the group consisting of an epoxy silane compound, an amino silane compound, a mercapto silane compound, a (meth)acryl silane compound, a vinyl silane compound, an alkyl silane compound, an isocyanate group-containing silane compound, an isocyanurate group-containing silane compound, a fluorene skeleton-containing silane compound, and a benzotriazole group-containing silane compound.
[4] The photosensitive resin composition according to any one of [1] to [3], in which a content of (E) the organosilane compound is 1 to 40 parts by mass with respect to 100 parts by mass of a content of (A) the acid-modified vinyl group-containing resin.
[5] The photosensitive resin composition according to any one of [1] to [4], in which (C) the photopolymerization initiator includes at least one selected from the group consisting of an acetophenone compound, a thioxanthone compound, a benzophenone compound, an oxime ester compound, and an acylphosphine oxide compound.
[6] A photosensitive element including: a support film; and a photosensitive layer formed on the support film, in which the photosensitive layer contains the photosensitive resin composition according to any one of [1] to [5].
[7] A printed wiring board including a permanent resist containing a cured product of the photosensitive resin composition according to any one of [1] to [5].
[8] A method for producing a printed wiring board, the method including: a step of forming a photosensitive layer on a substrate using the photosensitive resin composition according to any one of [1] to [5]; a step of exposing and developing the photosensitive layer to form a resist pattern; and a step of curing the resist pattern to form a permanent resist.
[9] A method for producing a printed wiring board, the method including: a step of forming a photosensitive layer on a substrate using the photosensitive element according to [6]; a step of exposing and developing the photosensitive layer to form a resist pattern; and a step of curing the resist pattern to form a permanent resist.

### Advantageous Effects of Invention

According to the present disclosure, it is possible to provide a photosensitive resin composition capable of forming a permanent resist that is excellent in resolution, thermal shock resistance, heat resistance, and insulation properties, a photosensitive element and a printed wiring board each obtained using the photosensitive resin composition, and a method for producing a printed wiring board.

### BRIEF DESCRIPTION OF DRAWINGS

FIG. 1 is a cross-sectional view schematically illustrating a photosensitive element according to the present embodiment.

### DESCRIPTION OF EMBODIMENTS

Hereinafter, an embodiment of the present disclosure will be specifically described, but the present disclosure is not limited thereto. In the following embodiments, constituent elements (also including element steps and the like) are not essential unless otherwise specified or unless it is clearly considered essential in principle. The same also applies to numerical values and their ranges, and do not unduly limit the present disclosure.

In the present disclosure, the term “layer” encompasses a structure having a shape formed on a part of a surface as well as a structure having a shape formed on the entire surface when observed in plan view. In the present disclosure, the term “step” includes not only an independent step, but also a step that cannot be clearly distinguished from another step as long as the intended purpose of the step is achieved. In the present disclosure, the numerical range indicated using “to” indicates a range that includes the numerical values before and after “to” as the minimum and maximum values, respectively. In a numerical range described in stages in the present disclosure, the upper limit or lower limit of a numerical range at a certain stage may be replaced with the upper limit or lower limit of a numerical range at another stage. In a numerical range described in the present disclosure, the upper limit or lower limit of the numerical range may be replaced with a value shown in Examples. In the present disclosure, “A or B” is only required to include either A or B, and may include both A and B. Unless otherwise stated, the following materials may be used singly or in combination of two or more kinds thereof. In the present disclosure, in a case where a plurality of substances corresponding to each component are present in a composition, the content of each component in the composition means the total amount of the plurality of substances present in the composition, unless otherwise stated.

In the present disclosure, the term “solids” refers to non-volatile components excluding volatile substances such as water and diluents contained in the photosensitive resin composition, and refers to components that do not evaporate or vaporize but remain when the resin composition is dried, and also includes components that are liquid, syrup-like, or wax-like at room temperature (25° C., the same applies below).

### [Photosensitive Resin Composition]

The photosensitive resin composition according to the present embodiment contains (A) an acid-modified vinyl group-containing resin, (B) a photopolymerizable compound, (C) a photopolymerization initiator, (D) an inorganic filler, and (E) an organosilane compound, and the inorganic filler includes a surface-treated filler. The photosensitive resin composition according to the present embodiment is a negative photosensitive resin composition, and a cured film of the photosensitive resin composition can be suitably used as a permanent resist.

The photosensitive resin composition for permanent resist according to the present embodiment can form a permanent resist that is excellent in resolution, thermal shock resistance, heat resistance, and insulation properties. The photosensitive resin composition according to the present embodiment is excellent in close contact properties to inner layer circuits and electric insulation reliability, which are required for photosensitive resin compositions used in the production of printed wiring boards, and is useful as an interlayer insulating layer for multilayer printed wiring boards. Hereinafter, each component contained in the photosensitive resin composition according to the present embodiment will be described in detail.

### <Component (A): Acid-Modified Vinyl Group-Containing Resin>

The photosensitive resin composition according to the present embodiment contains an acid-modified vinyl group-containing resin as a component (A). The acid-modified vinyl group-containing resin is not particularly limited as long as it has a vinyl bond, which is a photopolymerizable ethylenically unsaturated bond, and an alkali-soluble acidic group.

Examples of the group having an ethylenically unsaturated bond, which is contained in the component (A) include a vinyl group, an allyl group, a propargyl group, a butenyl group, an ethynyl group, a phenylethynyl group, a maleimide group, a nadimide group, and a (meth)acryloyl group. Among these, from the viewpoints of reactivity and resolution, the group having an ethylenically unsaturated bond may be a (meth)acryloyl group. Examples of the acidic group contained in the component (A) include a carboxy group, a sulfo group, and a phenolic hydroxyl group. Among these, from the viewpoint of resolution, the acidic group may be a carboxy group.

The component (A) may be an acid-modified vinyl group-containing epoxy derivative obtained by reacting (a) an epoxy resin (hereinafter, referred to as “component (a)”) with (b) an ethylenically unsaturated group-containing organic acid (hereinafter, referred to as “component (b)”) to obtain a resin (A′) (hereinafter, referred to as “component (A′)”) and reacting the resin (A′) with (c) a saturated or unsaturated group-containing polybasic acid anhydride (hereinafter, referred to as “component (c)”).

Examples of the acid-modified vinyl group-containing epoxy derivative include acid-modified epoxy (meth)acrylate. The acid-modified epoxy (meth)acrylate is a resin obtained by subjecting an epoxy (meth)acrylate, which is a reaction product of the component (a) with the component (b), to acid modification with the component (c). As the acid-modified epoxy (meth)acrylate, for example, an addition reaction product can be used in which a saturated or unsaturated polybasic acid anhydride is added to an esterification product obtained by reacting an epoxy resin with a vinyl group-containing monocarboxylic acid.

Examples of the component (A) include an acid-modified vinyl group-containing resin (A1) (hereinafter, referred to as “component (A1)”) obtained using a bisphenol novolac type epoxy resin (a1) (hereinafter, referred to as “epoxy resin (a1)”) as the component (a) and an acid-modified vinyl group-containing resin (A2) (hereinafter, referred to as “component (A2)”) obtained using an epoxy resin (a2) other than the epoxy resin (a1) (hereinafter, referred to as “epoxy resin (a2)”) as the component (a). These can be used singly or in combination of two or more kinds thereof.

(Epoxy Resin (a1))

Examples of the epoxy resin (a1) include epoxy resins having a structural unit represented by the following Formula (I) or (II). The epoxy resin (a1) may be an epoxy resin having a structural unit represented by formula (I).

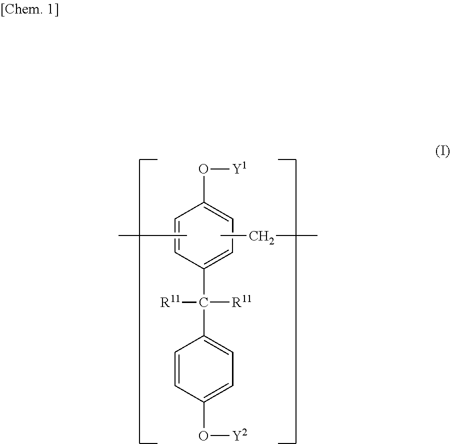

In Formula (I), R¹¹ represents a hydrogen atom or a methyl group, and a plurality of R¹¹'s may be the same as or different from each other. Y¹ and Y² each independently represent a hydrogen atom or a glycidyl group, provided that at least either of Y¹ or Y² is a glycidyl group. R¹¹ may be a hydrogen atom from the viewpoint of suppressing the occurrence of undercut and improving the linearity of the resist pattern contour and resolution, and Y¹ and Y² may be a glycidyl group from the viewpoint of further improving the thermal shock resistance.

The number of structural units represented by Formula (I) in the epoxy resin (a1) is 1 or more, and may be 10 to 100, 15 to 80, or 15 to 70. When the number of structural units is in the above range, the linearity of the resist pattern contour, close contact properties to a copper substrate, heat resistance, and electric insulation are likely to be improved. Here, the number of structural units indicates an integer value in a single molecule, and indicates a rational number that is an average value in an aggregate of plural kinds of molecules. Hereinafter, the same applies to the number of structural units of a structural unit.

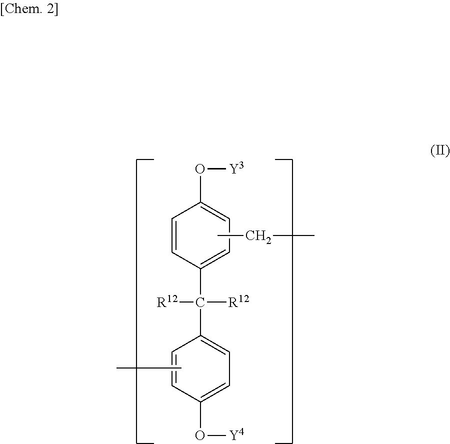

In Formula (II), R¹² represents a hydrogen atom or a methyl group, and a plurality of R¹²'s may be the same as or different from each other. Y³ and Y⁴ each independently represent a hydrogen atom or a glycidyl group, provided that at least either of Y³ or Y⁴ is a glycidyl group. R¹² may be a hydrogen atom from the viewpoint of suppressing the occurrence of undercut and improving the linearity of the resist pattern contour and resolution, and Y³ and Y⁴ may be a glycidyl group from the viewpoint of further improving the thermal shock resistance.

The number of structural units represented by Formula (II) in the epoxy resin (a1) is 1 or more, and may be 10 to 100, 15 to 80, or 15 to 70. When the number of structural units is in the above range, the linearity of the resist pattern contour, close contact properties to a copper substrate, and heat resistance are likely to be improved.

An epoxy resin represented by Formula (II) where R¹² is a hydrogen atom and Y³ and Y⁴ are a glycidyl group is commercially available as EXA-7376 series (trade name, manufactured by DIC Corporation). An epoxy resin represented by Formula (II) where R¹² is a methyl group and Y³ and Y⁴ are a glycidyl group is commercially available as EPON SU8 series (trade name, manufactured by Mitsubishi Chemical Corporation).

(Epoxy Resin (a2))

The epoxy resin (a2) is not particularly limited as long as it is an epoxy resin different from the epoxy resin (a1), but may be at least one selected from the group consisting of a novolac type epoxy resin, a bisphenol A type epoxy resin, a bisphenol F type epoxy resin, a triphenolmethane type epoxy resin, and a biphenyl type epoxy resin from the viewpoint of suppressing the occurrence of undercut and improving the linearity of the resist pattern contour, close contact properties to a copper substrate, and resolution.

Examples of the novolac type epoxy resin include epoxy resins having a structural unit represented by the following Formula (III). Examples of the bisphenol A type epoxy resin or bisphenol F type epoxy resin include epoxy resins having a structural unit represented by the following Formula (IV). Examples of the triphenolmethane type epoxy resin include epoxy resins having a structural unit represented by the following Formula (V). Examples of the biphenyl type epoxy resin include epoxy resins having a structural unit represented by the following Formula (VI).

The epoxy resin (a2) is preferably a novolac type epoxy resin having a structural unit represented by the following Formula (III). Examples of the novolac type epoxy resin having such a structural unit include a novolac type epoxy resin represented by the following Formula (III′).

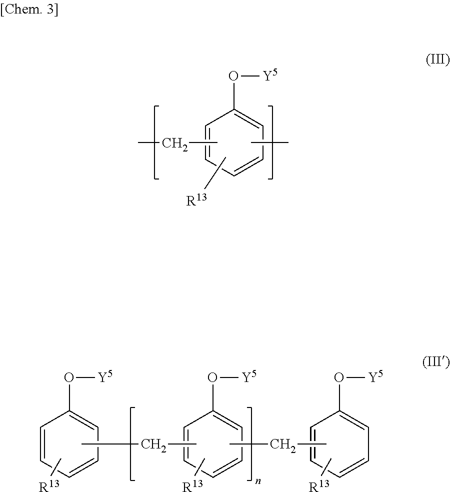

In Formulas (III) and (III′), R¹³ represents a hydrogen atom or a methyl group, and Y⁵ represents a hydrogen atom or a glycidyl group, provided that at least one Y⁵ is a glycidyl group. In Formula (III′), n₁ is a number of 1 or more, and a plurality of R¹³'s and a plurality of Y⁵'s may be the same as or different from each other, respectively. From the viewpoint of suppressing the occurrence of undercut and improving the linearity of the resist pattern contour and resolution, R¹³ may be a hydrogen atom.

In Formula (III′), the molar ratio of Y⁵ that is a hydrogen atom to Y⁵ that is a glycidyl group may be 0/100 to 30/70 or 0/100 to 10/90 from the viewpoint of suppressing the occurrence of undercut and improving the linearity of the resist pattern contour and resolution. n₁ is 1 or more, but may be 10 to 200, 30 to 150, or 30 to 100. When n₁ is in the above range, the linearity of the resist pattern contour, close contact properties to a copper substrate, and heat resistance are likely to be improved.

Examples of the novolac type epoxy resin represented by Formula (III′) include a phenol novolac type epoxy resin and a cresol novolac type epoxy resin. These novolac type epoxy resins can be obtained by, for example, reacting a phenol novolac resin or a cresol novolac resin with epichlorohydrin by a known method.

As the phenol novolac type epoxy resin or cresol novolac type epoxy resin represented by Formula (III′), for example, YDCN-701, YDCN-702, YDCN-703, YDCN-704, YDCN-704L, YDPN-638, and YDPN-602 (all trade names, manufactured by NIPPON STEEL Chemical & Material Co., Ltd.), DEN-431 and DEN-439 (all trade names, manufactured by The Dow Chemical Company), EOCN-120, EOCN-102S, EOCN-103S, EOCN-104S, EOCN-1012, EOCN-1025, EOCN-1027, and BREN (all trade names, manufactured by Nippon Kayaku Co., Ltd.), EPN-1138, EPN-1235, and EPN-1299 (all trade names, manufactured by BASF), and N-730, N-770, N-865, N-665, N-673, VH-4150, and VH-4240 (all trade names, manufactured by DIC Corporation) are commercially available.

Preferred examples of the epoxy resin (a2) include a bisphenol A type epoxy resin or bisphenol F type epoxy resin having a structural unit represented by the following Formula (IV). Examples of the epoxy resin having such a structural unit include a bisphenol A type epoxy resin or bisphenol F type epoxy resin represented by the following Formula (IV′).

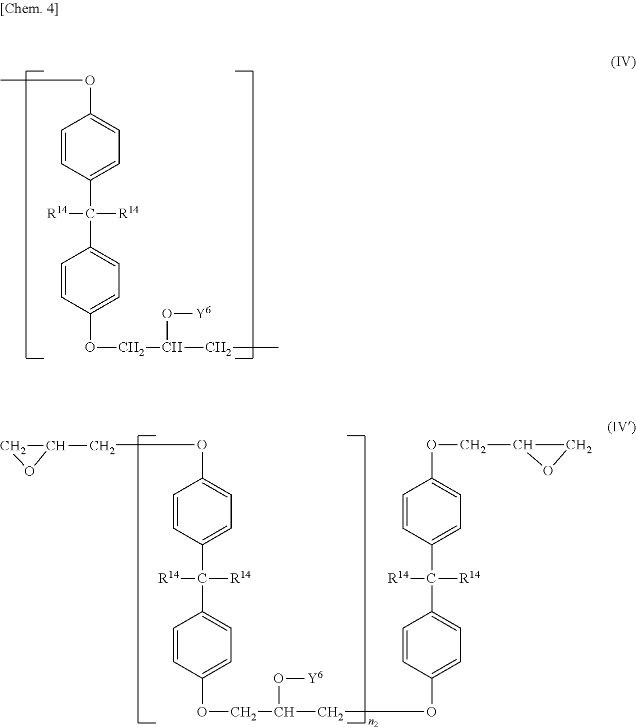

In Formulas (IV) and (IV′), R¹⁴ represents a hydrogen atom or a methyl group, and a plurality of R¹⁴'s may be the same as or different from each other, and Y⁶ represents a hydrogen atom or a glycidyl group. In Formula (IV′), n₂ represents a number of 1 or more, and when n₂ is 2 or more, a plurality of Y⁶'s may be the same as or different from each other, and at least one Y⁶ is a glycidyl group.

R¹⁴ may be a hydrogen atom from the viewpoint of suppressing the occurrence of undercut and improving the linearity of the resist pattern contour and resolution, and Y⁶ may be a glycidyl group from the viewpoint of further improving the thermal shock resistance. n₂ represents 1 or more, but may be 10 to 100, 10 to 80, or 15 to 60. When n₂ is in the above range, the linearity of the resist pattern contour, close contact properties to a copper substrate, and heat resistance are likely to be improved.

The bisphenol A type epoxy resin or bisphenol F type epoxy resin represented by Formula (IV) where Y⁶ is a glycidyl group can be obtained by, for example, reacting the hydroxyl group (—OY⁶) of a bisphenol A type epoxy resin or bisphenol F type epoxy resin represented by Formula (IV) where Y⁶ is a hydrogen atom with epichlorohydrin.

In order to promote the reaction of a hydroxyl group with epichlorohydrin, the reaction may be conducted in a polar organic solvent such as dimethylformamide, dimethylacetamide, or dimethyl sulfoxide at a reaction temperature of 50° C. to 120° C. in the presence of an alkali metal hydroxide. When the reaction temperature is in the above range, the reaction does not proceed too slow and side reactions can be suppressed.

As the bisphenol A type epoxy resin or bisphenol F type epoxy resin represented by Formula (IV′), for example, jER807, jER815, jER825, jER827, jER828, jER834, jER1001, jER1004, jER1007 and jER1009 (all trade names, manufactured by Mitsubishi Chemical Corporation), DER-330, DER-301, and DER-361 (all trade names, manufactured by The Dow Chemical Company), and YD-8125, YDF-170, YDF-175S, YDF-2001, YDF-2004, and YDF-8170 (all trade names, manufactured by NIPPON STEEL Chemical & Material Co., Ltd.) are commercially available.

Preferred examples of the epoxy resin (a2) include triphenolmethane type epoxy resins having a structural unit represented by the following Formula (V). Examples of the triphenolmethane type epoxy resins having such a structural unit include a triphenolmethane type epoxy resin represented by the following Formula (V′).

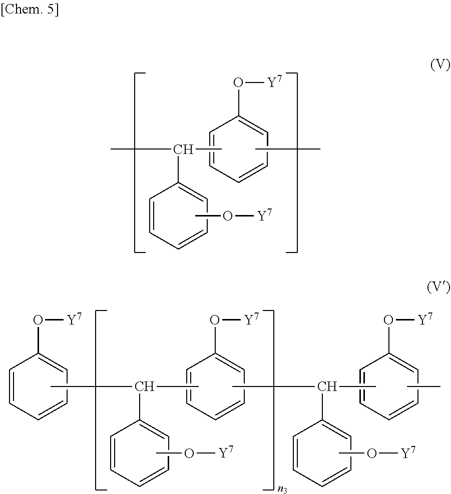

In Formulas (V) and (V′), Y⁷ represents a hydrogen atom or a glycidyl group, a plurality of Y⁷'s may be the same as or different from each other, and at least one Y⁷ is a glycidyl group. In Formula (V′), n₃ represents a number of 1 or more.

From the viewpoint of suppressing the occurrence of undercut and missing of the upper part and improving the linearity of the resist pattern contour and resolution, the molar ratio of Y⁷ that is a hydrogen atom to Y⁷ that is a glycidyl group in Y⁷'s may be 0/100 to 30/70. As can be seen from this molar ratio as well, at least one Y⁷ is a glycidyl group. n₃ is 1 or more, but may be 10 to 100, 15 to 80, or 15 to 70. When n₃ is in the above range, the linearity of the resist pattern contour, close contact properties to a copper substrate, and heat resistance are likely to be improved.

As the triphenolmethane type epoxy resin represented by Formula (V′), for example, FAE-2500, EPPN-501H, and EPPN-502H (all trade names, manufactured by Nippon Kayaku Co., Ltd.) are commercially available.

Preferred examples of the epoxy resin (a2) include biphenyl type epoxy resins having a structural unit represented by the following Formula (VI). Examples of the biphenyl type epoxy resins having such a structural unit include a biphenyl type epoxy resin represented by the following Formula (VI′).

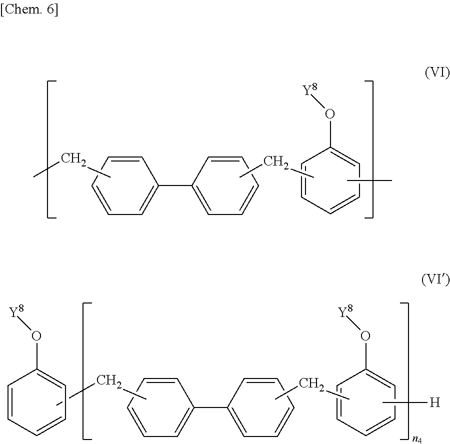

In Formulas (VI) and (VI′), Y⁸ represents a hydrogen atom or a glycidyl group, a plurality of Y⁸'s may be the same as or different from each other, and at least one Y⁸ is a glycidyl group. In Formula (V′), n₄ represents a number of 1 or more.

As the biphenyl type epoxy resin represented by Formula (VI′), for example, NC-3000, NC-3000-L, NC-3000-H, NC-3000-FH-75M, NC-3100, and CER-3000-L (all trade names, manufactured by Nippon Kayaku Co., Ltd.) are commercially available.

The epoxy resin (a2) is preferably at least one selected from the group consisting of a novolac type epoxy resin having a structural unit represented by Formula (III), a bisphenol A type epoxy resin having a structural unit represented by Formula (IV), and a bisphenol F type epoxy resin having a structural unit represented by Formula (IV), and is more preferably a bisphenol F type epoxy resin having a structural unit represented by formula (IV).

From the viewpoint of thermal shock resistance, warpage reduction, and resolution, the component (A1) obtained using a bisphenol novolac type epoxy resin having a structural unit represented by Formula (I) as the component (a1) and the component (A2) obtained using a bisphenol A type epoxy resin or a bisphenol F type epoxy resin having a structural unit represented by Formula (IV) as the component (a2) may be used in combination.

### (Ethylenically Unsaturated Group-Containing Organic Acid (b))

Examples of the component (b) include acrylic acid; acrylic acid derivatives such as a dimer of acrylic acid, methacrylic acid, β-furfuryl acrylic acid, β-styryl acrylic acid, cinnamic acid, crotonic acid, and α-cyanocinnamic acid; a half-ester compound which is a reaction product of a hydroxyl group-containing (meth)acrylate with a dibasic acid anhydride; a half-ester compound which is a reaction product of a vinyl group-containing monoglycidyl ether or vinyl group-containing monoglycidyl ester with a dibasic acid anhydride. The component (b) can be used singly or in combination of two or more kinds thereof.

The half-ester compound can be obtained by, for example, reacting a hydroxyl group-containing (meth)acrylate, vinyl group-containing monoglycidyl ether or vinyl group-containing monoglycidyl ester with a dibasic acid anhydride.

Examples of the hydroxyl group-containing (meth)acrylate, vinyl group-containing monoglycidyl ether, and vinyl group-containing monoglycidyl ester include hydroxyethyl (meth)acrylate, hydroxypropyl (meth)acrylate, hydroxybutyl (meth)acrylate, polyethylene glycol mono(meth)acrylate, trimethylolpropane di(meth)acrylate, pentaerythritol tri(meth)acrylate, dipentaerythritol penta(meth)acrylate, and glycidyl (meth)acrylate.

Examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

In the reaction of the component (a) with the component (b), the component (a) may be reacted with the component (b) at a ratio so that the equivalent of the component (b) is 0.6 to 1.05 or 0.8 to 1.0 with respect to 1 equivalent of the epoxy group in the component (a). By conducting the reaction at such a ratio, the photosensitivity increases and the linearity of the resist pattern contour tends to be excellent.

The components (a) and (b) can be reacted in a state of being dissolved in an organic solvent. Examples of the organic solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. The organic solvents may be used singly or in combination of two or more kinds thereof.

A catalyst may be used to promote the reaction of the component (a) with the component (b). Examples of the catalyst include triethylamine, benzylmethylamine, methyltriethylammonium chloride, benzyltrimethylammonium chloride, benzyltrimethylammonium bromide, benzyltrimethylammonium iodide, and triphenylphosphine. The catalysts may be used singly or in combination of two or more kinds thereof.

The amount of the catalyst used may be 0.01 to 10 parts by mass, 0.05 to 2 parts by mass, or 0.1 to 1 part by mass with respect to 100 parts by mass of the total amount of the components (a) and (b) from the viewpoint of promoting the reaction of the component (a) with the component (b).

In the reaction of the component (a) with the component (b), a polymerization inhibitor may be used for the purpose of preventing polymerization during the reaction. Examples of the polymerization inhibitor include hydroquinone, methylhydroquinone, hydroquinone monomethyl ether, catechol, and pyrogallol. The polymerization inhibitors may be used singly or in combination of two or more kinds thereof. The amount of the polymerization inhibitor used may be 0.01 to 1 part by mass, 0.02 to 0.8 parts by mass, or 0.04 to 0.5 parts by mass with respect to 100 parts by mass of the total amount of the components (a) and (b) from the viewpoint of improving stability.

The temperature for the reaction of the component (a) with the component (b) may be 60° C. to 150° C., 80° C. to 120° C., or 90° C. to 110° C. from the viewpoint of productivity.

The component (A′) obtained by reacting the component (a) with the component (b) has a hydroxyl group formed by a ring-opening addition reaction of the epoxy group in the component (a) with the carboxyl group in the component (b). By further reacting the component (A′) with the component (c), an acid-modified vinyl group-containing resin is obtained in which the hydroxyl groups in the component (A′) (including the hydroxyl groups originally present in the component (a)) and the acid anhydride groups in the component (c) are half-esterified.

### (Polybasic Acid Anhydride (c))

Examples of the component (c) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among these, the component (c) may be tetrahydrophthalic anhydride from the viewpoint of resolution. The component (c) may be used singly or in combination of two or more kinds thereof.

The temperature for the reaction of the component (A′) with the component (c) may be 50° C. to 150° C., 60° C. to 120° C., or 70° C. to 100° C. from the viewpoint of productivity.

If necessary, as the component (a), for example, a hydrogenated bisphenol A type epoxy resin may be used together or a styrene-maleic acid-based resin such as a hydroxyethyl (meth)acrylate-modified product of a styrene-maleic anhydride copolymer may be used together.

In the reaction of the component (A′) with the component (c), for example, by reacting the component (A′) with the component (c) so that the equivalent of the component (c) is 0.1 to 1.0 with respect to 1 equivalent of the hydroxyl group in the component (A′), the acid value of the component (A) can be adjusted.

The acid value of component (A) may be 30 mgKOH/g to 150 mgKOH/g, 40 mgKOH/g to 120 mgKOH/g, or 50 mgKOH/g to 100 mgKOH/g. When the acid value of the component (A) is 30 mgKOH/g or more, the solubility of the photosensitive resin composition in a dilute alkaline solution tends to be excellent. When the acid value of the component (A) is 150 mgKOH/g or less, the electrical properties of the permanent resist are likely to be improved.

The weight average molecular weight (Mw) of the component (A) is not particularly limited. From the viewpoints of resolution, close contact properties, heat resistance, and electric insulation, the Mw of the component (A) may be 3000 to 30000, 4000 to 25000, or 5000 to 18000.

The Mw can be measured by gel permeation chromatography (GPC). With regard to the Mw, for example, measurement can be performed under the following GPC conditions and the value converted using the calibration curve of standard polystyrene can be taken as the Mw. For creation of the calibration curve, a five-sample set (“PStQuick MP-H” and “PStQuick B”, manufactured by Tosoh Corporation) can be used as standard polystyrene.
GPC system: High-speed GPC system “HCL-8320GPC” (manufactured by Tosoh Corporation)
Detector: Differential refractometer or UV detector (manufactured by Tosoh Corporation)
Column: TSKgel SuperMultipore HZ-H column (column length: 15 cm, column inner diameter: 4.6 mm) (manufactured by Tosoh Corporation)
Eluent: Tetrahydrofuran (THF)
Measurement temperature: 40° C.
Flow rate: 0.35 mL/min
Sample concentration: 10 mg/5 mL THF
Injection volume: 20 μL

The content of the component (A) in the photosensitive resin composition may be 20% to 80% by mass, 25% to 70% by mass, or 3% to 50% by mass based on the total solid amount in the photosensitive resin composition from the viewpoint of improving the heat resistance, electrical properties, and chemical resistance of the permanent resist.

In a case where the component (A1) and the component (A2) are used in combination as the component (A), the total content of the components (A1) and (A2) in the component (A) may be 80% to 100% by mass, 90% to 100% by mass, 95% to 100% by mass, or 100% by mass based on the total amount of the component (A) from the viewpoints of linearity of the resist pattern contour, resistance to electroless plating, and heat resistance. In a case where the component (A1) or the component (A2) is used singly, the content can be appropriately selected from the above range.

In a case where the component (A1) and the component (A2) are used in combination as the component (A), the mass ratio (A1)/(A2) may be 20/80 to 90/10, 30/70 to 80/20, 40/60 to 75/25, or 50/50 to 70/30 from the viewpoints of linearity of the resist pattern contour, resistance to electroless plating, and heat resistance.

### <Component (B): Photopolymerizable Compound>

The photosensitive resin composition according to the present embodiment contains a photopolymerizable compound as a component (B). The component (B) is not particularly limited as long as it is a compound having a functional group that exhibits photopolymerizability. Examples of the functional group that exhibits photopolymerizability include groups having an ethylenically unsaturated bond, such as a vinyl group, an allyl group, a propargyl group, a butenyl group, an ethynyl group, a phenylethynyl group, a maleimide group, a nadimide group, and a (meth)acryloyl group. From the viewpoint of reactivity, the component (B) may include a compound having a (meth)acryloyl group.

Examples of the component (B) include hydroxyalkyl (meth)acrylates such as 2-hydroxyethyl (meth)acrylate and 2-hydroxypropyl (meth)acrylate; mono- or di(meth)acrylates of glycols such as ethylene glycol, methoxytetraethylene glycol, and polyethylene glycol; (meth)acrylamide compounds such as N,N-dimethyl(meth)acrylamide and N-methylol (meth)acrylamide; aminoalkyl(meth)acrylates such as N,N-dimethylaminoethyl (meth)acrylate; polyvalent (meth)acrylates of polyhydric alcohols or their ethylene oxide or propylene oxide adducts such as hexanediol, trimethylolpropane, pentaerythritol, ditrimethylolpropane, dipentaerythritol, and tris(hydroxyethyl) isocyanurate; (meth)acrylate compounds of ethylene oxide or propylene oxide adducts of phenol compounds, such as phenoxyethyl(meth)acrylate and polyethoxydi(meth)acrylate of bisphenol A; (meth)acrylates of glycidyl ethers, such as glycerin diglycidyl ether, trimethylolpropane triglycidyl ether, and triglycidyl isocyanurate; and melamine (meth)acrylate. The component (B) can be used singly or in combination of two or more kinds thereof.

The content of the component (B) may be 0.1% to 15% by mass, 0.1% to 10% by mass, 0.5% to 8% by mass, or 2% to 7% by mass based on the total solid amount in the photosensitive resin composition. The exposed portion is less likely to be eluted during development when the content of the component (B) is 0.1% by mass or more, and the heat resistance is likely to be improved when the content is 15% by mass or less.

### <Component (C): Photopolymerization Initiator>

The photosensitive resin composition according to the present embodiment contains a photopolymerization initiator as a component (C). The component (C) is not particularly limited as long as it can polymerize the photopolymerizable compound that is the component (B). The component (C) can be used singly or in combination of two or more kinds thereof.

Examples of the component (C) include benzoin compounds such as benzoin, benzoin methyl ether, and benzoin isopropyl ether; acetophenone compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-butanone-1,2-methyl-[4-(methylthio)phenyl]-2-morpholino-1-propane, and N,N-dimethylaminoacetophenone; anthraquinone compounds such as 2-methylanthraquinone, 2-ethylanthraquinone, 2-tert-butylanthraquinone, 1-chloroanthraquinone, 2-amylanthraquinone, and 2-aminoanthraquinone; thioxanthone compounds such as 2,4-dimethylthioxanthone, 2,4-diethylthioxanthone, 2-chlorothioxanthone, and 2,4-diisopropylthioxanthone; ketal compounds such as acetophenone dimethyl ketal and benzyl dimethyl ketal; benzophenone compounds such as benzophenone, methylbenzophenone, 4,4′-dichlorobenzophenone, 4,4′-bis(diethylamino)benzophenone, Michler's ketone, and 4-benzoyl-4′-methyldiphenyl sulfide; imidazole compounds such as 2-(o-chlorophenyl)-4,5-diphenylimidazole dimer, 2-(0-chlorophenyl)-4,5-di(m-methoxyphenyl) imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine compounds such as 9-phenylacridine and 1,7-bis(9,9′-acridinyl)heptane; oxide compounds such as 2,4,6-acylphosphine trimethylbenzoyldiphenylphosphine oxide; oxime ester compounds such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(O-acetyloxime), and 1-phenyl-1,2-propanedione-2-[O-(ethoxycarbonyl) oxime]; and tertiary amine compounds such as N,N-dimethylaminobenzoic acid ethyl ester, N,N-dimethylaminobenzoic acid isoamyl ester, pentyl-4-dimethylaminobenzoate, triethylamine, and triethanolamine.

The component (C) preferably includes at least one selected from the group consisting of an acetophenone compound, a thioxanthone compound, a benzophenone compound, an oxime ester compound, and an acylphosphine oxide compound. The component (C) can be selected depending on the desired performance. The component (C) may include an acetophenone compound, a thioxanthone compound, or an acylphosphine oxide compound from the viewpoint of improving solder heat resistance, may include an acylphosphine oxide compound from the viewpoint of improving the curing properties of the bottom by photobleaching, or may include an acetophenone compound from the viewpoint of being less likely to volatilize and generate outgas.

The content of the component (C) is not particularly limited, but may be 0.2% to 15% by mass, 0.4% to 5% by mass, or 0.6% to 1.0% by mass based on the total solid amount in the photosensitive resin composition. The exposed portions are less likely to be eluted during development when the content of the component (C) is 0.2% by mass or more, and a decrease in heat resistance is likely to be suppressed when the content is 15% by mass or less.

### <Component (D): Inorganic Filler>

The photosensitive resin composition according to the present embodiment contains an inorganic filler including a surface-treated filler as a component (D). The surface-treated filler can be obtained by treating the surface of an inorganic filler with a surface treatment agent. By treating the surface of an inorganic filler, the adhesive strength with the component (A) at the filler interface is improved, and the heat resistance and thermal shock resistance of the permanent resist can be improved. The surface-treated filler may be used singly or in combination of two or more kinds thereof.

Examples of the inorganic filler include silica (SiO₂), alumina (Al₂O₃), titania (TiO₂), tantalum oxide (Ta₂O₅), zirconia (ZrO₂), silicon nitride (Si₃N₄), barium titanate (BaO·TiO₂), barium carbonate (BaCO₃), magnesium carbonate (MgCO₃), aluminium hydroxide (Al(OH)₃), magnesium hydroxide (Mg(OH)₂), lead titanate (PbO·TiO₂), lead zirconate titanate (PZT), lead lanthanum zirconate titanate (PLZT), gallium oxide (Ga₂O₃), spinel (MgO·Al₂O₃), mullite (3Al₂O₃·2SiO₂), cordierite (2MgO·₂Al₂O₃/5SiO₂), talc (3MgO·₄SiO₂H₂O), aluminium titanate (TiO₂Al₂O₃), yttria-containing zirconia (Y₂O₃·ZrO₂), barium silicate (BaO·₈SiO₂), boron nitride (BN), calcium carbonate (CaCO₃), barium sulfate (BaSO₄), calcium sulfate (CaSO₄), zinc oxide (ZnO), magnesium titanate (MgO·TiO₂), hydrotalcite, mica, calcined kaolin, and carbon (C). The inorganic filler may include silica from the viewpoint that heat resistance can be improved, may include barium sulfate from the viewpoint that heat resistance and adhesive strength can be improved, or may include silica and barium sulfate in combination.

The surface treatment agent is not particularly limited as long as it is an organic compound that has the function of covering the surface of an inorganic filler and inhibiting the reaction of an organosilane compound that is the component (E) with the uncovered inorganic filler. The surface treatment agent desirably has a functional group that can form a bond with the functional group on the inorganic filler surface, and examples thereof include a functional group, such as a silyl group, that can form a bond with a silanol group present on the silica surface by hydrolysis.

Examples of the surface treatment agent include an organozirconium compound, an organotitanium compound, an organoaluminium compound, and an organosilane compound. The method for treating the surface of an inorganic filler is not particularly limited, and for example, silica may be treated with an organosilane compound as a silane coupling agent. As the surface-treated filler, a commercially available product can also be purchased.

Examples of the organozirconium compound include zirconium tetrapropoxide, zirconium tetrabutoxide, normal propyl zirconate, normal butyl zirconate, and zirconium tetra acetylacetonate. Examples of the organotitanium compound include tetraethyl orthotitanate, tetrakis(2-ethylhexyl) orthotitanate, tetraisopropyl titanate, tetra-n-butyl titanate, and titanium acetylacetonate. Examples of the organoaluminium compound include aluminium sec-butoxide. Examples of the organosilane compound include an epoxy silane compound, an amino silane compound, a mercapto silane compound, a (meth)acryl silane compound, a vinyl silane compound, an alkyl silane compound, an isocyanate group-containing silane compound, an isocyanurate group-containing silane compound, a fluorene skeleton-containing silane compound, and a benzotriazole group-containing silane compound.

Examples of the epoxy silane compound include 3-glycidoxypropyltrimethoxysilane, 3-glycidoxypropylmethyldimethoxysilane, 3-glycidoxypropyltriethoxysilane, 3-glycidoxypropylmethyldiethoxysilane, and 2-(3,4-epoxycyclohexyl)ethyltrimethoxysilane.

Examples of the amino silane compound include 3-aminopropyltrimethoxysilane, 3-aminopropyltriethoxysilane, 3-(2-aminoethyl)aminopropyltrimethoxysilane, 3-(2-aminoethyl)aminopropylmethyldimethoxysilane, 3-phenylaminopropyltrimethoxysilane, and N-(1,3-dimethylbutylidene)-3-aminopropyltriethoxysilane.

Examples of the mercapto silane compound include 3-mercaptopropyltrimethoxysilane, 3-mercaptopropylmethyldimethoxysilane, and 3-mercaptopropyltriethoxysilane.

Examples of the (meth)acryl silane compound include 3-methacryloxypropyltrimethoxysilane, 3-methacryloxypropylmethyldimethoxysilane, and 3-methacryloxypropyltriethoxysilane.

Examples of the vinyl silane compound include vinyltriacetoxysilane, vinyltrimethoxysilane, vinyltriethoxysilane, vinyltriisopropoxysilane, allyltrimethoxysilane, diallyldimethylsilane, and p-styryltrimethoxysilane.

Examples of the alkyl silane compound include dimethoxydiphenylsilane. Examples of the isocyanate group-containing silane compound include tris-(trimethoxysilylpropyl) isocyanurate. Examples of the isocyanurate group-containing silane compound include 3-isocyanatepropyltriethoxysilane.

Examples of the fluorene skeleton-containing silane compound include products under the trade names “SC-001” and “SC-003” manufactured by Osaka Gas Chemicals Co., Ltd. Examples of the benzotriazole group-containing silane compound include a product under the trade name “X-12-1214A” manufactured by Shin-Etsu Chemical Co., Ltd.

The elemental composition of aluminium on the surface of the inorganic filler that has undergone surface treatment with an organoaluminium compound or an organosilane compound can be appropriately selected from 0.5 atomic % to 10 atomic %, 1 atomic % to 5 atomic %, or 1.5 atomic % to 3.5 atomic %. The elemental composition of silicon on the surface of the inorganic filler can be appropriately selected from 0.5 atomic % to 10 atomic %, 1 atomic % to 5 atomic %, or 1.5 atomic % to 3.5 atomic %. The elemental composition of carbon on the surface of the inorganic filler can be appropriately selected from 10 atomic % to 30 atomic %, 15 atomic % to 25 atomic %, or 18 atomic % to 23 atomic %. These elemental compositions can be measured by XPS (X-ray photoelectron spectroscopy).

The silica filler that has undergone surface treatment with an organoaluminium compound or an organosilane compound may be prepared by treating the ADMAFINE Silica series of ADMATECHS COMPANY LIMITED with the silane compounds described above. As barium sulfate that has undergone surface treatment with an organoaluminium compound or an organosilane compound, a product under the trade name “BFN40DC” manufactured by Nippon Solvay K.K. is commercially available.

From the viewpoint of resolution, the average particle size of the component (D) may be 0.01 μm to 5 μm, 0.05 μm to 3 μm, 0.1 μm to 2 μm, or 0.15 μm to 1 μm. The average particle size of the component (D) is the average particle size of the component (D) in a state of being dispersed in the photosensitive resin composition, and is a value obtained by measurement according to the following procedure.

The photosensitive resin composition is diluted with a solvent (methyl ethyl ketone) 1000 times, and the particle size distribution of the particles dispersed in the solvent is measured at a refractive index of 1.38 using a submicron particle analyzer (manufactured by Beckman Coulter, Inc., trade name “N5”) in conformity with the international standard ISO 13321. The particle size at an integrated value of 50% (volume basis) in the particle size distribution is taken as the average particle size. The average particle size of the component (D) contained in the photosensitive layer and cured film formed using the photosensitive resin composition can also be measured according to the same procedure.

The content of the surface-treated filler is not particularly limited, but may be 15% to 70% by mass, 20% to 65% by mass, 25% to 60% by mass, 25% to 50% by mass, or 25% to 45% by mass based on the total solid amount in the photosensitive resin composition. When the content of the surface-treated filler is within the above range, the strength, heat resistance, resolution and the like of the permanent resist tend to be excellent.

### <Component (E): Organosilane Compound>

In the photosensitive resin composition according to the present embodiment, the component (E) is not particularly limited, and any known and commonly used organosilane compound can be used. The organosilane compound may be used singly or in combination of two or more kinds thereof.

Examples of the organosilane compound include an epoxy silane compound, an amino silane compound, a mercapto silane compound, a (meth)acryl silane compound, a vinyl silane compound, an alkyl silane compound, an isocyanate group-containing silane compound, an isocyanurate group-containing silane compound, a fluorene skeleton-containing silane compound, and a benzotriazole group-containing silane compound.

The component (E) may be selected from the organosilane compounds exemplified as the surface treatment agent in the component (D). The component (E) may include a benzotriazole group-containing silane compound particularly from the viewpoint of close contact properties to a copper substrate, or may include a fluorene skeleton-containing silane compound from the viewpoint of heat resistance.

The content of the component (E) is not particularly limited, but may be 1 to 50 parts by mass, 1 to 25 parts by mass, 1.5 to 25 parts by mass, 2 to 20 parts by mass, or 2 to 15 parts by mass with respect to 100 parts by mass of the content of the component (D). When the content of the component (E) is in the above range, the permanent resist tends to maintain favorable developability, close contact properties and heat resistance while exhibiting excellent thermal shock resistance. The content of the component (E) may be 1 to 40 parts by mass, 1.5 to 30 parts by mass, 2 to 25 parts by mass, or 2.5 to 20 parts by mass with respect to 100 parts by mass of the content of the component (A) from the viewpoint of further enhancing the thermal shock resistance and heat resistance of the permanent resist. The content of the component (E) may be 0.5% to 10% by mass, 0.8% to 9% by mass, 1% to 8% by mass, or 1.2% to 7% by mass based on the total solid amount in the photosensitive resin composition.

### <Component (F): Pigment>

The photosensitive resin composition according to the present embodiment may further contain a pigment as a component (F) from the viewpoint of improving the appearance, such as the concealment of conductor pattern. As the component (F), a colorant that produces a desired color when the wiring (conductor pattern) is concealed and the like can be used. The component (F) may be used singly or in combination of two or more kinds thereof.

Examples of the component (F) include phthalocyanine blue, phthalocyanine green, iodine green, diazo yellow, crystal violet, titanium oxide, carbon black, and naphthalene black.

The content of the component (F) may be 0.01% to 5.0% by mass, 0.03% to 3.0% by mass, or 0.05% to 2.0% by mass based on the total solid amount in the photosensitive resin composition from the viewpoints of easily distinguishing the production apparatus and further concealing the wiring.

### <Component (G): Curing Agent>

The photosensitive resin composition according to the present embodiment may further contain a curing agent as a component (G). Examples of the component (G) include a compound that itself is cured by heat, ultraviolet light or the like or a compound that is cured through the reaction with a carboxyl group or a hydroxyl group in the component (A) by heat, ultraviolet light or the like. By using a curing agent, the heat resistance, close contact properties, chemical resistance and the like of the permanent resist can be improved.

Examples of the component (G) include thermosetting compounds such as an epoxy compound, a blocked isocyanate, a melamine compound, and an oxazoline compound. Examples of the melamine compound include triaminotriazine, hexamethoxymelamine, and hexabutoxylated melamine. The component (G) can be used singly or in combination of two or more kinds thereof.

As the epoxy compound, for example, those exemplified as the component (a) can be used. The epoxy compound may be liquid or solid at room temperature (25° C.). Examples of the epoxy compound include a bisphenol A type epoxy resin, a bisphenol F type epoxy resin, a hydrogenated bisphenol A type epoxy resin, a brominated bisphenol A type epoxy resin, a novolac type epoxy resin, a bisphenol S type epoxy resin, a biphenyl type epoxy resin, a naphthalene type epoxy resin, a dicyclo type epoxy resin, a hydantoin type epoxy resin, a triglycidyl isocyanurate, and a bixylenol type epoxy resin. The component (G) may include at least one selected from the group consisting of bisphenol type epoxy resins such as a bisphenol A type epoxy resin and a bisphenol F type epoxy resin and novolac type epoxy resins.

As the blocked isocyanate, an addition reaction product of a polyisocyanate compound with an isocyanate blocking agent is used. Examples of the melamine compound include triaminotriazine, hexamethoxymelamine, and hexabutoxylated melamine. Among these, an epoxy compound (epoxy resin) is preferred from the viewpoint of further improving the heat resistance of the cured film.

The content of the component (G) may be 2% to 40% by mass, 3% to 30% by mass, or 5% to 20% by mass based on the total solid amount in the photosensitive resin composition. When the content of the component (G) is in the above range, the heat resistance of the permanent resist to be formed can be further improved while more favorable developability is maintained.

In a case where an epoxy compound is used as the component (G), a curing accelerator for the epoxy resin may be used together for the purpose of further improving various properties of the permanent resist such as heat resistance, close contact properties, and chemical resistance.

Examples of the curing accelerator include imidazole derivatives such as 2-methylimidazole, 2-ethyl-4-methylimidazole, 1-benzyl-2-methylimidazole, 2-phenylimidazole, and 2-phenyl-4-methyl-5-hydroxymethylimidazole; guanamines such as acetoguanamine and benzoguanamine; polyamines such as diaminodiphenylmethane, m-phenylenediamine, m-xylylenediamine, diaminodiphenylsulfone, dicyandiamide, urea, urea derivatives, melamine, and polybasic hydrazides; organic acid salts or epoxy adducts thereof; amine complexes of boron trifluoride; and triazine derivatives such as ethyldiamino-s-triazine, 2,4-diamino-s-triazine, and 2,4-diamino-6-xylyl-s-triazine. The content of the curing accelerator may be 0.01% to 30% by mass or 0.1% to 20% by mass based on the total solid amount in the photosensitive resin composition from the viewpoint of improving reliability.

### <Component (H): Elastomer>

The photosensitive resin composition according to the present embodiment may further contain an elastomer as a component (H). By adding the component (H) to the photosensitive resin composition, the decrease in flexibility and adhesive strength caused by distortion (internal stress) inside the resin due to curing shrinkage of the component (A) can be suppressed. In other words, the flexibility and adhesive strength of the permanent resist to be formed from the photosensitive resin composition can be improved.

Examples of the component (H) include a styrene-based elastomer, an olefin-based elastomer, a urethane-based elastomer, a polyester-based elastomer, a polyamide-based elastomer, an acrylic elastomer, and a silicone-based elastomer. A thermoplastic elastomer is composed of a hard segment component that contributes to heat resistance and strength and a soft segment component that contributes to flexibility and toughness. The component (H) can be used singly or in combination of two or more kinds thereof.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As a component constituting the styrene-based elastomer, in addition to styrene, styrene derivatives such as α-methylstyrene, 3-methylstyrene, 4-propylstyrene, and 4-cyclohexylstyrene can be used.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer, copolymers of non-conjugated dienes, such as dicyclopentadiene, 1,4-hexadiene, cyclooctadiene, methylene norbornene, ethylidene norbornene, butadiene, and isoprene, with α-olefins, epoxy-modified polybutadiene, and a carboxylic acid-modified butadiene-acrylonitrile copolymer.

The epoxy-modified polybutadiene preferably has a hydroxyl group at a molecular terminal, more preferably has a hydroxyl group at both molecular terminals, and still more preferably has a hydroxyl group only at both molecular terminals. The number of hydroxyl groups in the epoxy-modified polybutadiene may be 1 or more, preferably 1 to 5, more preferably 1 or 2, and still more preferably 2.

As the urethane-based elastomer, a compound composed of a hard segment formed from a low molecular weight (short chain) diol and a diisocyanate and a soft segment formed from a high molecular weight (long chain) diol and a diisocyanate can be used. Examples of the low molecular weight diol include ethylene glycol, propylene glycol, 1,4-butanediol, and bisphenol A. Examples of the high molecular weight diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate).

The number average molecular weight (Mn) of the low molecular weight diol may be from 48 to 500. The Mn of the high molecular weight diol may be from 500 to 10000. As the urethane-based elastomer, for example, PANDEX T-2185 and T-2983N (manufactured by DIC Corporation) and Miractran E790 (manufactured by Nippon Miractran Co., Ltd.) are commercially available.

As the polyester-based elastomer, a compound obtained by polycondensation of a dicarboxylic acid or a derivative thereof with a diol compound or a derivative thereof can be used. Examples of the dicarboxylic acid include aromatic dicarboxylic acids such as terephthalic acid, isophthalic acid, and naphthalenedicarboxylic acid and aromatic dicarboxylic acids in which hydrogen atoms in the aromatic nucleus of these dicarboxylic acids are substituted with a methyl group, an ethyl group, a phenyl group and the like; aliphatic dicarboxylic acids having 2 to 20 carbon atoms, such as adipic acid, sebacic acid, and dodecanedicarboxylic acid; and alicyclic dicarboxylic acids such as cyclohexanedicarboxylic acid.

Examples of the diol compound include aliphatic diols such as ethylene glycol, 1,3-propanediol, 1,4-butanediol, 1,6-hexanediol, and 1,10-decanediol; alicyclic diols such as 1,4-cyclohexanediol; and aromatic diols such as bisphenol A, bis-(4-hydroxyphenyl) methane, bis-(4-hydroxy-3-methylphenyl) propane, and resorcinol.

As the polyester-based elastomer, a multiblock copolymer composed of an aromatic polyester (for example, polybutylene terephthalate) moiety as a hard segment component and an aliphatic polyester (for example, polytetramethylene glycol) moiety as a soft segment component can be used. There are various grades of polyester-based elastomers depending on the kind, ratio, and molecular weight of the hard and soft segments. As the polyester-based elastomer, for example, Hytrel (manufactured by Toray Celanese Co., Ltd., “Hytrel” is a registered trademark), PELPRENE (manufactured by TOYOBO CO., LTD., “PELPRENE” is a registered trademark), and Espel (manufactured by Showa Denko Materials Co., Ltd., “Espel” is a registered trademark) are commercially available.

As the acrylic elastomer, a compound containing a structural unit based on an acrylic ester as a main component can be used. Examples of the acrylic acid ester include ethyl acrylate, butyl acrylate, methoxyethyl acrylate, and ethoxyethyl acrylate. The acrylic elastomer may be a compound obtained by copolymerizing an acrylic acid ester and acrylonitrile, or may be a compound obtained by further copolymerizing the compound and a monomer having a functional group that serves as a crosslinking point. Examples of the monomer having a functional group include glycidyl methacrylate and allyl glycidyl ether. Examples of the acrylic elastomer include an acrylonitrile-butyl acrylate copolymer, an acrylonitrile-butyl acrylate-ethyl acrylate copolymer, and an acrylonitrile-butyl acrylate-glycidyl methacrylate copolymer.

Polyamide-based elastomers are broadly classified into two types of a polyether block amide type and a polyether ester block amide type, in which a polyamide is used as the hard segment and a polyether or polyester is used as the soft segment. Examples of the polyamide include polyamide-6, polyamide-11, and polyamide-12. Examples of the polyether include polyoxyethylene glycol, polyoxypropylene glycol, and polytetramethylene glycol.

The silicone-based elastomer is a compound of which the main component is an organopolysiloxane. Examples of the organopolysiloxane include polydimethylsiloxane, polymethylphenylsiloxane, and polydiphenylsiloxane. The silicone-based elastomer may be a compound in which a part of an organopolysiloxane is modified with a vinyl group, an alkoxy group, or the like.

The content of the component (H) may be 1 to 40 parts by mass, 4 to 30 parts by mass, 5 to 25 parts by mass, or 10 to 20 parts by mass with respect to 100 parts by mass of the content of the component (A). By setting the content of the component (H) in the above range, the unexposed portions of the photosensitive layer are more likely to be eluted by the developer, and the elastic modulus of the permanent resist in high temperature regions tends to further decrease.

### <Other Components>

In the photosensitive resin composition according to the present embodiment, if necessary, a diluent such as an organic solvent may be mixed in order to adjust the viscosity. Examples of the organic solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha.

In a case where a diluent is used, the content of the diluent in the photosensitive resin composition may be 10% to 50% by mass, 20% to 40% by mass, or 25% to 35% by mass. By setting the content of the diluent in the above range, the application properties of the photosensitive resin composition are improved and the formation of highly precise pattern is possible.

In the photosensitive resin composition according to the present embodiment, if necessary, various additives may be further mixed. Examples of the additives include polymerization inhibitors such as hydroquinone, methylhydroquinone, hydroquinone monomethyl ether, catechol, pyrogallol; thickeners such as Bentone and montmorillonite; silicone-based, fluorine-based and vinyl resin-based defoamers; silane coupling agents; and flame retardants such as a brominated epoxy compound, an acid-modified brominated epoxy compound, an antimony compound, a phosphate compound of a phosphorus-based compound, an aromatic condensed phosphate ester, and a halogen-containing condensed phosphate ester. These may be used singly or two or more kinds thereof may be used together.

The photosensitive resin composition according to the present embodiment can be prepared by uniformly mixing the respective components described above using a roll mill, a bead mill, or the like.

### [Photosensitive Element]

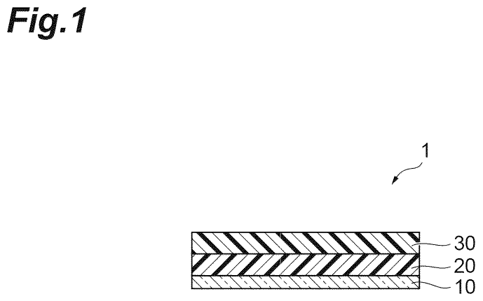

The photosensitive element according to the present embodiment includes a support film and a photosensitive layer containing the photosensitive resin composition described above. FIG. 1 is a cross-sectional view schematically illustrating the photosensitive element according to the present embodiment. As illustrated in FIG. 1, a photosensitive element 1 includes a support film 10 and a photosensitive layer 20 formed on the support film 10.

The photosensitive element 1 can be produced by, for example, applying the photosensitive resin composition according to the present embodiment onto the support film 10 by a known method such as reverse roll coating, gravure roll coating, comma coating, or curtain coating and then drying the coating film to form the photosensitive layer 20.

Examples of the support film include polyester films such as polyethylene terephthalate and polybutylene terephthalate; and polyolefin films such as polypropylene and polyethylene. The thickness of the support film may be, for example, 5 μm to 100 μm. The thickness of the photosensitive layer may be, for example, 10 μm to 50 μm, 15 μm to 40 μm, or 20 μm to 30 μm.

For drying of the coating film, hot air drying or drying using far infrared rays or near infrared rays can be adopted. The drying temperature may be 60° C. to 120° C., 70° C. to 110° C., or 80° C. to 100° C. The drying time may be 1 minute to 60 minutes, 2 minutes to 30 minutes, or 5 minutes to 20 minutes.

A protective film 30 that covers the photosensitive layer 20 may further be provided on the photosensitive layer 20. In the photosensitive element 1, the protective film 30 can also be laminated on the surface of the photosensitive layer 20 opposite to the surface in contact with the support film 10. As the protective film 30, for example, a polymer film such as polyethylene or polypropylene may be used. The protective film may be the same film as or a different film from the support film.

### [Printed Wiring Board]

The printed wiring board according to the present embodiment includes a permanent resist containing a cured product of the photosensitive resin composition according to the present embodiment. Since the printed wiring board according to the present embodiment includes a permanent resist containing a cured product of the photosensitive resin composition according to the present embodiment, the generation of cracks in the permanent resist can be reduced.

The method for producing a printed wiring board according to the present embodiment includes a step of forming a photosensitive layer on a substrate using the photosensitive resin composition described above or the photosensitive element described above; a step of exposing and developing the photosensitive layer to form a resist pattern; and a step of curing the resist pattern to form a permanent resist. Hereinafter, an example of each step will be described.

First, a metal-clad laminate such as a copper-clad laminate is prepared as a substrate, and a photosensitive layer is formed on the substrate. In a case where a photosensitive resin composition is used, the photosensitive resin composition may be applied onto the substrate by a method such as a screen printing method, a spraying method, a roll coating method, a curtain coating method, or an electrostatic coating method, and the formed coating film may be dried at 60° C. to 110° C. to form a photosensitive layer. The thickness of the coating film may be 10 μm to 200 μm, 15 μm to 150 μm, 20 μm to 100 μm, or 23 μm to 50 μm. In a case where a photosensitive element is used, the photosensitive layer may be formed by thermally laminating the photosensitive layer of the photosensitive element on the substrate using a laminator.

Next, a negative mask is brought into contact with the photosensitive layer directly or via a transparent film such as a support film, the photosensitive layer is exposed by being irradiated with actinic light, and then the unexposed portions are dissolved and removed with a developer to form a resist pattern. Examples of the actinic light include electron beams, ultraviolet light, and X-rays, and ultraviolet light is preferred. As the light source, a low pressure mercury lamp, a high pressure mercury lamp, an ultra-high pressure mercury lamp, a halogen lamp, and the like can be used. The exposure may be 10 mJ/cm² to 2000 mJ/cm², 100 mJ/cm² to 1500 mJ/cm², or 300 mJ/cm² to 1000 mJ/cm². Examples of the developing method include a dipping method and a spraying method. As the developer, for example, an aqueous alkali solution of potassium hydroxide, sodium hydroxide, sodium carbonate, potassium carbonate, tetramethylammonium hydroxide or the like can be used.

Next, the formed resist pattern is subjected to at least one treatment of post-exposure or post-heating for sufficient curing, whereby a permanent resist can be formed. The exposure in post-exposure may be 100 mJ/cm² to 5000 mJ/cm², 500 mJ/cm² to 2000 mJ/cm², or 700 mJ/cm² to 1500 J/cm². The heating temperature for post-heating may be 100° C. to 200° C., 120° C. to 180° C., or 135° C. to 165° C. The heating time for post-heating may be 5 minutes to 12 hours, 10 minutes to 6 hours, or 30 minutes to 2 hours. The thickness of the permanent resist may be 10 μm to 50 μm, 15 μm to 40 μm, or 20 μm to 30 μm. Thereafter, wiring is formed by etching, whereby a printed wiring board is produced.

The permanent resist according to the present embodiment can be used as an interlayer insulating layer or a surface protection layer of a semiconductor element. A semiconductor element having an interlayer insulating layer or surface protection layer formed from a cured film of the photosensitive resin composition described above, and an electronic device including the semiconductor element can be produced. The semiconductor element may be, for example, a memory, a package, or the like having a multilayer wiring structure, a rewiring structure, or the like. Examples of electronic devices include mobile phones, smartphones, tablet terminals, personal computers, and hard disk suspensions. It is possible to provide a semiconductor element and an electronic device that are excellent in reliability by including a patterned cured film that is formed from the photosensitive resin composition according to the present embodiment.

### EXAMPLES

Hereinafter, the present disclosure will be described in more detail with reference to Examples, but the present disclosure is not limited to these Examples.

### Synthesis Example 1

Into a flask equipped with a stirrer, a reflux condenser, and a thermometer, 350 parts by mass of bisphenol F novolac type epoxy resin (manufactured by DIC Corporation, trade name “EXA-7376”, a bisphenol F novolac type epoxy resin having a structural unit represented by Formula (II) where Y³ and Y⁴ are glycidyl groups and R¹² is a hydrogen atom, epoxy equivalent: 186 g/eq), 70 parts by mass of acrylic acid, 0.5 parts by mass of methylhydroquinone, and 120 parts by mass of carbitol acetate were charged, and reacted at 90° C. while being stirred to completely dissolve the mixture. Next, the obtained solution was cooled to 60° C., 2 parts by mass of triphenylphosphine was added, and the mixture was reacted at 100° C. until the acid value of the solution became 1 mgKOH/g or less. To the solution after the reaction, 98 parts by mass of tetrahydrophthalic anhydride (THPAC) and 85 parts by mass of carbitol acetate were added, and the mixture was reacted at 80° C. for 6 hours. Thereafter, the reaction solution was cooled to room temperature (25° C.) to obtain a solution of THPAC-modified bisphenol F novolac type epoxy acrylate (A-1) (solid concentration: 73% by mass) as a component (A1).

### Synthesis Example 2

Into a flask equipped with a stirrer, a reflux condenser, and a thermometer, 1052 parts by mass of bisphenol F type epoxy resin (a bisphenol F type epoxy resin having a structure represented by Formula (IV) where Y⁶ is a hydrogen atom and R¹⁴ is a hydrogen atom, epoxy equivalent: 526), 144 parts by mass of acrylic acid, 1 part by mass of methylhydroquinone, 850 parts by mass of carbitol acetate, and 100 parts by mass of solvent naphtha were charged, and reacted at 70° C. while being stirred to completely dissolve the mixture. Next, the obtained solution was cooled to 50° C., and 2 parts by mass of triphenylphosphine and 75 parts by mass of solvent naphtha were added, and the mixture was reacted at 100° C. until the acid value of the solution became 1 mgKOH/g or less. To the solution after the reaction, 745 parts by mass of THPAC, 75 parts by mass of carbitol acetate, and 75 parts by mass of solvent naphtha were added, and the mixture was reacted at 80° C. for 6 hours. Thereafter, the reaction solution was cooled to room temperature (25° C.) to obtain a solution of THPAC-modified bisphenol F type epoxy acrylate (A-2) (solid concentration: 62% by mass) as a component (A2).

The following materials were prepared as components (B) to (H).
B-1: DPHA, dipentaerythritol hexaacrylate (manufactured by Nippon Kayaku Co., Ltd.)
C-1:2-Methyl-[4-(methylthio)phenyl]morpholino-1-propanone (manufactured by IGM Resins B.V., trade name “Ominirad 907”)
C-2:2,4-Diethylthioxanthone (manufactured by Nippon Kayaku Co., Ltd., trade name “DETX-S”)
C-3:4,4′-Bis(diethylamino)benzophenone (manufactured by Hodogaya Chemical Co., Ltd.)
C-4:1-[9-Ethyl-6-(2-methylbenzoyl)-9H-carbazol-3-yl]ethanone 1-(O-acetyloxime) (manufactured by BASF Japan Ltd., trade name “Irgacure OXE02”)
D-1: Surface-treated silica filler (silica filler prepared by subjecting a silica filler (manufactured by ADMATECHS COMPANY LIMITED, trade name “SO-C2”, average particle size: 0.5 μm) to surface treatment with a vinyl silane compound)
D-2: Surface-treated barium sulfate (manufactured by Nippon Solvay K.K., trade name “BFN40DC”, average particle size: 0.6 μm)
D-3: Surface-treated silica filler (filler prepared by covering a silica filler (manufactured by Denka Company Limited, trade name “SFP-20”, average particle size: 0.4 μm) with zirconium tetrapropoxide (manufactured by Tokyo Chemical Industry Co., Ltd.))
D-4: Untreated silica filler (manufactured by Denka Company Limited, trade name “SFP-20”, average particle size: 0.4 μm)
E-1:3-Glycidoxypropyltrimethoxysilane (manufactured by Shin-Etsu Chemical Co., Ltd., trade name “KBM-1003”)
E-2: Fluorene skeleton-containing silane compound (manufactured by Osaka Gas Chemicals Co., Ltd., trade name “SC-001”)
E-3: Benzotriazole group-containing silane compound (manufactured by Shin-Etsu Chemical Co., Ltd., trade name “X-12-1241A”)
E-4: Zirconium tetrapropoxide (Tokyo Chemical Industry Co., Ltd.)
E-5: Tetraethyl orthotitanate (Tokyo Chemical Industry Co., Ltd.)
F-1: Phthalocyanine-based pigment (manufactured by SANYO COLOR WORKS, LTD.)
G-1: Novolac type polyfunctional epoxy resin (manufactured by Nippon Kayaku Co., Ltd., trade name “RE-306”)
G-2: Bisphenol A type epoxy resin (manufactured by Mitsubishi Chemical Corporation, trade name “jER828”)
H-1: Epoxy-modified polybutadiene (manufactured by Daicel Corporation, trade name “PB-3600”)
H-2: Polyester-based elastomer (manufactured by Toray Celanese Co., Ltd., trade name “Hytrel 4057N”)

### [Photosensitive Resin Composition]

The respective components were blended in the amounts (parts by mass, in terms of solid) shown in Table 1, Table 2 or Table 3, and kneaded using a three-roll mill. Thereafter, carbitol acetate was added so that the solid concentration became 70% by mass, thereby obtaining a photosensitive resin composition.

### [Photosensitive Element]

As a support film, a polyethylene terephthalate film having a thickness of 25 μm (manufactured by Toyobo Film Solutions Co., Ltd., trade name “G2-25”) was prepared. A solution obtained by diluting the photosensitive resin composition with methyl ethyl ketone was applied onto the support film so as to have a thickness after drying of 25 μm, and dried at 75° C. for 30 minutes using a hot air convection dryer to form a photosensitive layer. Next, a polyethylene film (manufactured by TAMAPOLY CO., LTD., trade name “NF-15”) as a protective film was pasted to the surface of the photosensitive layer opposite to the surface in contact with the support film, thereby obtaining a photosensitive element.

### (Resolution)

A copper-clad laminated substrate having a thickness of 0.6 mm (manufactured by Showa Denko Materials Co., Ltd., trade name “MCL-E-67”) was prepared. While peeling off and removing the protective film from the photosensitive element, the photosensitive layer was laminated on the copper-clad laminated substrate at a pressure for pressure bonding of 0.4 MPa, a press hot plate temperature of 80° C., a vacuuming time of 25 seconds, and a lamination press time of 25 seconds using a press-type vacuum laminator (manufactured by MEIKI CO., LTD., trade name “MVLP-500”), thereby obtaining a laminate. Next, a negative mask having an opening pattern of a predetermined size (opening diameter size: 30, 40, 50, 60, 70, 80, 90, 100, 110, 120, 150, or 200 μm) was brought into close contact with the support film of the laminate, and the photosensitive layer was exposed at an exposure that resulted in 13 complete curing steps on a step tablet (manufactured by Showa Denko Materials Co., Ltd.) using an ultraviolet exposure system (manufactured by Oak Co., Ltd., trade name “EXM-1201”). Thereafter, the support film was peeled off from the photosensitive layer, and spray development was performed at a pressure of 1.765−10⁵ Pa for 60 seconds using a 1% by mass aqueous solution of sodium carbonate to dissolve and develop the unexposed portions. Next, the developed photosensitive layer was exposed at an exposure of 2000 mJ/cm² using an ultraviolet exposure system, and then heated at 170° C. for 1 hour to fabricate a test piece having a cured film on which an opening pattern of a predetermined size was formed on a copper-clad laminated substrate. The test piece was observed under an optical microscope and evaluated according to the following criteria.
A: The minimum opening diameter size was 30 μm or less.
B: The minimum opening diameter size was more than 30 μm and less than 50 μm.
C: The minimum opening diameter size was more than 50 μm.

### (Resist Pattern Shape)

The test piece was cast with an embedding resin (trade name “jER828” manufactured by Mitsubishi Chemical Corporation and triethylenetetramine were used as an epoxy resin and a curing agent, respectively), sufficiently cured, and then polished using a polishing machine (manufactured by Refine Tec Ltd., trade name “Refine Polisher”) to cut out a cross section of the opening pattern of the cured film. The obtained cross section of the opening pattern was observed under a metallurgical microscope and evaluated according to the following criteria.
A: Undercut or missing of the resist upper part was not observed, and the linearity of the pattern contour was favorable.
B: Undercut or missing of the resist upper part was observed, or the linearity of the pattern contour was poor.

### (Thermal Shock Resistance)

The test piece fabricated in the evaluation of resolution was subjected to a temperature cycle test in which one cycle consisted of 30 minutes at −65° C. and 30 minutes at 150° C., and the test piece was observed visually and under an optical microscope at the time points of 1000 cycles, 2000 cycles and 3000 cycles and evaluated according to the following criteria.
S: Generation of cracks was not observed after 3000 cycles.
A: Generation of cracks was not observed after 2000 cycles, but generation of cracks was observed after 3000 cycles.
B: Generation of cracks was not observed after 1000 cycles, but generation of cracks was observed after 2000 cycles.
C: Generation of cracks was observed after 1000 cycles.

### (Heat Resistance)

The test piece fabricated in the evaluation of resolution was placed in an environment of 150° C., and the test piece was observed visually and under an optical microscope after 1000 hours and 2000 hours and evaluated according to the following criteria.
A: Generation of cracks was not observed after 2000 hours.
B: Generation of cracks was not observed after 1000 hours, but generation of cracks was observed after 2000 hours.
C: Generation of cracks was not observed after 1000 hours.

### (Insulation Properties)

A test piece was fabricated in the same manner as in “1. Evaluation of resolution” above except that a bismaleimide triazine substrate on which an interdigitated array electrode (line/space=10/10 μm) was formed was used instead of the copper-clad laminated substrate in the fabrication of the test piece in the evaluation of resolution, this was exposed to conditions of 135° C., 85% RH, and 3.3 V, and the change in resistance value was measured using a migration tester (manufactured by Kusumoto Chemicals, Ltd., trade name “SIR13”). Thereafter, the extent of the occurrence of migration was observed under an optical microscope and evaluated according to the following criteria.
A: In more than 200 hours, the resistance value did not decrease to 10⁻⁶Ω or less while migration did not occur in the permanent mask resist.
B: In 100 hours or more and less than 200 hours, the resistance value decreased to 10⁻⁶Ω or less while migration did not occur in the permanent mask resist.
C: In less than 100 hours, the resistance value decreased to 10⁻⁶Ω or less while migration did not occur in the permanent mask resist.

TABLE 1

| Example | | 1 | 2 | 3 | 4 | 5 | 6 | 7 |
|---|---|---|---|---|---|---|---|---|
| A | A-1 | 18.3 | 18.3 | 18.3 | 18.3 | 18.3 | 18.3 | 18.3 |
| | A-2 | 18.3 | 18.3 | 18.3 | 18.3 | 18.3 | 18.3 | 18.3 |
| B | B-1 | 7.3 | 7.3 | 7.3 | 7.3 | 7.3 | 7.3 | 7.3 |
| C | C-1 | 0.9 | 0.9 | 0.9 | 0.9 | 0.9 | 0.9 | 0.9 |
| | C-2 | 0.1 | 0.1 | 0.1 | 0.1 | 0.1 | 0.1 | 0.1 |
| | C-3 | 0.1 | 0.1 | 0.1 | 0.1 | 0.1 | 0.1 | 0.1 |
| | C-4 | 0.1 | 0.1 | 0.1 | 0.1 | 0.1 | 0.1 | 0.1 |
| D | D-1 | 30.1 | 30.1 | 30.1 | 30.1 | 30.1 | 30.1 | — |
| | D-2 | — | — | — | — | — | — | 30.1 |
| E | E-1 | 1.5 | 6.0 | — | — | — | — | 1.5 |
| | E-2 | — | — | 1.5 | — | — | — | — |
| | E-3 | — | — | — | 1.5 | — | — | — |
| | E-4 | — | — | — | — | 1.5 | — | — |
| | E-5 | — | — | — | — | — | 1.5 | — |
| F | F-1 | 1.2 | 1.2 | 1.2 | 1.2 | 1.2 | 1.2 | 1.2 |
| G | G-1 | 10.7 | 10.7 | 10.7 | 10.7 | 10.7 | 10.7 | 10.7 |
| | G-2 | 5.6 | 5.6 | 5.6 | 5.6 | 5.6 | 5.6 | 5.6 |
| H | H-1 | 3.8 | 3.8 | 3.8 | 3.8 | 3.8 | 3.8 | 3.8 |
| | H-2 | 2.0 | 2.0 | 2.0 | 2.0 | 2.0 | 2.0 | 2.0 |

| | | | | | | | |
|---|---|---|---|---|---|---|---|
| Resolution | A | A | A | A | A | A | A |
| Resist pattern shape | A | A | A | A | A | A | A |
| Thermal shock resistance | S | S | S | S | A | A | S |
| Heat resistance | A | A | A | A | A | A | A |
| Insulation properties | A | A | A | A | A | A | A |

TABLE 2

| Example | | 8 | 9 | 10 | 11 | 12 | 13 | 14 | 15 |
|---|---|---|---|---|---|---|---|---|---|
| A | A-1 | 18.3 | 18.3 | 18.3 | 18.3 | 18.3 | 18.3 | 18.3 | 18.3 |
| | A-2 | 18.3 | 18.3 | 18.3 | 18.3 | 18.3 | 18.3 | 18.3 | 18.3 |
| B | B-1 | 7.3 | 7.3 | 7.3 | 7.3 | 7.3 | 7.3 | 7.3 | 7.3 |
| C | C-1 | 0.9 | 0.9 | 0.9 | 0.9 | 0.9 | 0.9 | 0.9 | 0.9 |
| | C-2 | 0.1 | 0.1 | 0.1 | 0.1 | 0.1 | 0.1 | 0.1 | 0.1 |
| | C-3 | 0.1 | 0.1 | 0.1 | 0.1 | 0.1 | 0.1 | 0.1 | 0.1 |
| | C-4 | 0.1 | 0.1 | 0.1 | 0.1 | 0.1 | 0.1 | 0.1 | 0.1 |
| D | D-3 | 30.1 | 30.1 | 30.1 | 30.1 | 30.1 | 30.1 | 30.1 | 30.1 |
| E | E-1 | 1.5 | — | 4.5 | — | 4.5 | 4.5 | 1.5 | — |
| | E-2 | — | — | — | — | 1.5 | — | — | — |
| | E-3 | — | — | — | — | — | — | — | — |
| | E-4 | — | 1.5 | — | 4.5 | — | 1.5 | 4.5 | 4.5 |
| | E-5 | — | — | — | — | — | — | — | 1.5 |
| F | F-1 | 1.2 | 1.2 | 1.2 | 1.2 | 1.2 | 1.2 | 1.2 | 1.2 |
| G | G-1 | 10.7 | 10.7 | 10.7 | 10.7 | 10.7 | 10.7 | 10.7 | 10.7 |
| | G-2 | 5.6 | 5.6 | 5.6 | 5.6 | 5.6 | 5.6 | 5.6 | 5.6 |
| H | H-1 | 3.8 | 3.8 | 3.8 | 3.8 | 3.8 | 3.8 | 3.8 | 3.8 |
| | H-2 | 2.0 | 2.0 | 2.0 | 2.0 | 2.0 | 2.0 | 2.0 | 2.0 |

| | | | | | | | | |
|---|---|---|---|---|---|---|---|---|
| Resolution | A | A | A | A | A | A | A | A |
| Resist pattern shape | A | A | A | A | A | A | A | A |
| Thermal shock resistance | S | A | S | A | S | A | A | A |
| Heat resistance | A | A | A | A | A | A | A | A |
| Insulation properties | A | A | A | A | A | A | A | A |

TABLE 3

| Comparative Example | | 1 | 2 | 3 |
|---|---|---|---|---|
| A | A-1 | 18.3 | 18.3 | 18.3 |
| | A-2 | 18.3 | 18.3 | 18.3 |
| B | B-1 | 7.3 | 7.3 | 7.3 |
| C | C-1 | 0.9 | 0.9 | 0.9 |
| | C-2 | 0.1 | 0.1 | 0.1 |
| | C-3 | 0.1 | 0.1 | 0.1 |
| | C-4 | 0.1 | 0.1 | 0.1 |
| D | D-1 | 30.1 | — | — |
| | D-4 | — | 30.1 | 30.1 |
| E | E-1 | — | 1.5 | — |
| F | F-1 | 1.2 | 1.2 | 1.2 |
| G | G-1 | 10.7 | 10.7 | 10.7 |
| | G-2 | 5.6 | 5.6 | 5.6 |
| H | H-1 | 3.8 | 3.8 | 3.8 |
| | H-2 | 2.0 | 2.0 | 2.0 |

| | | | |
|---|---|---|---|
| Resolution | A | A | C |
| Resist pattern shape | A | A | B |
| Thermal shock resistance | C | C | C |
| Heat resistance | B | B | B |
| Insulation properties | A | A | C |

### REFERENCE SIGNS LIST

1: photosensitive element, 10: support film, 20: photosensitive layer, and 30: protective film.

1. A photosensitive resin composition for permanent resist comprising: (A) an acid-modified vinyl group-containing resin; (B) a photopolymerizable compound; (C) a photopolymerization initiator; (D) an inorganic filler; and (E) an organosilane compound,
wherein (D) the inorganic filler includes a surface-treated filler.

2. The photosensitive resin composition according to claim 1, wherein the surface-treated filler is an inorganic filler that has undergone surface treatment with at least one surface treatment agent selected from the group consisting of an organozirconium compound, an organotitanium compound, an organoaluminium compound, and an organosilane compound.

3. The photosensitive resin composition according to claim 1, wherein (E) the organosilane compound includes at least one selected from the group consisting of an epoxy silane compound, an amino silane compound, a mercapto silane compound, a (meth)acryl silane compound, a vinyl silane compound, an alkyl silane compound, an isocyanate group-containing silane compound, an isocyanurate group-containing silane compound, a fluorene skeleton-containing silane compound, and a benzotriazole group-containing silane compound.

4. The photosensitive resin composition according to claim 1, wherein a content of (E) the organosilane compound is 1 to 40 parts by mass with respect to 100 parts by mass of a content of (A) the acid-modified vinyl group-containing resin.

5. The photosensitive resin composition according to claim 1, wherein (C) the photopolymerization initiator includes at least one selected from the group consisting of an acetophenone compound, a thioxanthone compound, a benzophenone compound, an oxime ester compound, and an acylphosphine oxide compound.

6. A photosensitive element comprising: a support film; and a photosensitive layer formed on the support film,
wherein the photosensitive layer contains the photosensitive resin composition according to claim 1.

7. A printed wiring board comprising a permanent resist containing a cured product of the photosensitive resin composition according to claim 1.

8. A method for producing a printed wiring board, the method comprising:
a step of forming a photosensitive layer on a substrate using the photosensitive resin composition according to claim 1;
a step of exposing and developing the photosensitive layer to form a resist pattern; and
a step of curing the resist pattern to form a permanent resist.

9. A method for producing a printed wiring board, the method comprising:
a step of forming a photosensitive layer on a substrate using the photosensitive element according to claim 6;
a step of exposing and developing the photosensitive layer to form a resist pattern; and
a step of curing the resist pattern to form a permanent resist.
